(19) United States
(12) Patent Application Publication
(10) Pub. No.: US 2026/0025940 A1
(43) Pub. Date: Jan. 22, 2026

(54) EMERGENCY RACK PROTECTION POLICY

(71) Applicant: Dell Products L.P., Round Rock, TX (US)

(72) Inventors: Douglas E. Messick, Austin, TX (US); Craig Anthony Klein, Elgin, TX (US)

(73) Assignee: Dell Products L.P., Round Rock, TX (US)

(21) Appl. No.: 18/777,677

(22) Filed: Jul. 19, 2024

(51) Int. Cl. H05K 7/14; H02J 3/00

(52) U.S. Cl. CPC H05K 7/1492; H02J 3/001; H05K 7/1498; H02J 2203/10; H02J 2310/16

(57) ABSTRACT

In systems and methods, a power distribution system provides power for multiple chassis installed in a rack. Two or more power supply units (PSUs) are installed in the chassis and may draw power redundantly from separate power grids supplying power to the rack. A first PSU of the chassis is coupled to one power grid and a second PSU of the same chassis is coupled to another power grid. Upon a failure in the second power grid, power drawn from the first power grid by the first PSU is limited according to a first current limit specified in a first emergency rack protection policy of the rack. Upon a failure in the first power grid, power drawn from the second power grid by the second PSU is limited according to a second current limit specified in a second emergency rack protection policy of the rack.

### FIELD

The present disclosure relates generally to Information Handling Systems (IHSs), and relates more particularly to providing redundant power supplies for use by IHSs.

### BACKGROUND

As the value and use of information continues to increase, individuals and businesses seek additional ways to process and store information. One option available to users is Information Handling Systems (IHSs). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

IHSs may be deployed in a wide variety of locations and may be utilized in a wide variety of computational tasks. In some scenarios, IHSs such as rack-mounted servers may be configured to perform critical functions such as, for example, implementing high-availability servers that may be located in a datacenter. Services that are provided using such high-availability datacenter systems must operate with minimum downtime. Accordingly, such IHSs may operate using redundant sources of power that are available within the datacenter.

### SUMMARY

In various embodiments, a power distribution system is provided for powering a chassis installed in a rack. The system may include: two or more power supply units (PSUs) installed in the chassis, wherein a first of the PSUs is coupled to a first power grid supplying power to the rack, and wherein a second of the PSUs is coupled to a second power grid supplying power to the rack, and wherein power drawn from the first power grid by the first PSU is limited according to a first current limit specified in a first emergency rack protection policy of the rack upon a failure in the second power grid, and wherein power drawn from the second power grid by the second PSU is limited according to a second current limit specified in a second emergency rack protection policy of the rack upon a failure in the first power grid.

In some embodiments, the first current limit specified in the first emergency rack protection policy is initiated in response to the failure in the second power grid, and wherein the second current limit specified in the second emergency rack protection policy is initiated in response to the failure in the first power grid. Some embodiments may further include a first power distribution unit (PDU) and a second PDU, wherein the first PSU draws power according to the first emergency rack protection policy from the first power grid via the first PDU, and wherein the second PSU draws power according to the second emergency rack protection policy from the second power grid via the second PDU. Some embodiments may further include a first whip coupling the first PDU to the first power grid and further comprising a second whip coupling the second PDU to the second power grid. Some embodiments may further include a third PSU that is installed in the chassis and that is coupled to the first power grid, wherein power drawn from the first power grid by the third PSU is limited according to a third current limit specified in a third emergency rack protection policy of the rack upon a failure in the second power grid. In some embodiments, the first current limit specified in the first emergency rack protection policy and the third current limit specified in the third emergency rack protection policy are selected to comply with power restrictions on the first whip coupling the first PDU to the first power grid. In some embodiments, the first PDU comprises a first bank of outlets and wherein the first PSU and the third PSU are coupled to the first power grid via the first bank of outlets of the first PDU. In some embodiments, the first current limit specified in the first emergency rack protection policy and the third current limit specified in the third emergency rack protection policy are selected to comply with power restrictions on the first bank of outlets of the first PDU. In some embodiments, a health of the first power grid is calculated in response to the failure in the second power grid, wherein the power drawn from the first power grid by the first PSU according to the first emergency rack protection policy is adjusted based on the health calculated for the first power grid.

### BRIEF DESCRIPTION OF THE DRAWINGS

The present invention(s) is/are illustrated by way of example and is/are not limited by the accompanying figures. Elements in the figures are illustrated for simplicity and clarity, and have not necessarily been drawn to scale.

FIG. 1 is a schematic illustration of certain components of a chassis including multiple IHSs, where the chassis is configured, according to some embodiments, to support redundant power supplies that are operated using emergency rack protection policies.

FIG. 2 is a rear-facing illustration of certain components of an rack configured, according to some embodiments, to support redundant power supplies that are operated using emergency rack protection policies.

FIG. 3 is an illustration of certain hardware components of a power distribution system configured, according to some embodiments, to support redundant power supplies that are operated using emergency rack protection policies.

FIG. 4 is a rear-facing illustration of certain components of another rack configured, according to some embodiments, to support two redundant power supplies that are operated using emergency rack protection policies.

FIG. 5 is a rear-facing illustration of certain components of another rack configured, according to some embodiments, to support four redundant power supplies that are operated using emergency rack protection policies.

### DETAILED DESCRIPTION

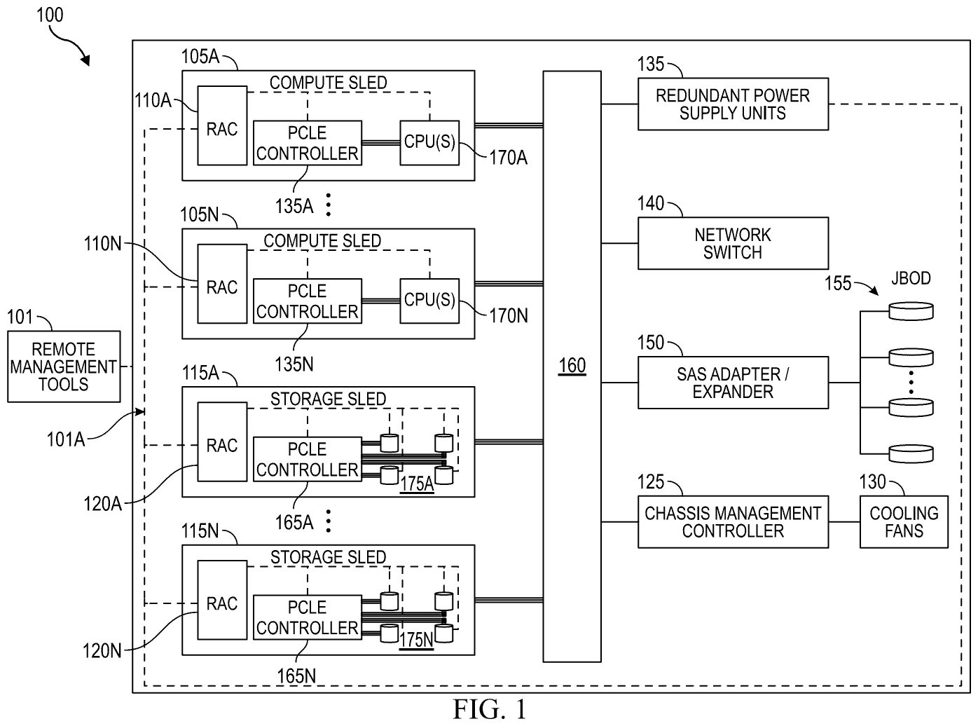

FIG. 1 is a schematic illustration of certain components of a chassis 100 that includes multiple IHSs, where the chassis is configured, according to some embodiments, to support redundant power supplies that are operated using emergency protection policies of the rack in which the chassis is installed. As described in additional detail below, chassis 100 embodiments may utilize redundant power sources that are used to power the removeable compute sled IHSs 105a-n, storage sled IHSs 115a-n and/or other computing components that are installed in chassis 100. Also as described in additional detail below, embodiments further support operation of chassis 100 utilizing emergency protection policies that configure the emergency use of available power upon a failure in one of the redundant power supplies provided by a rack in which chassis 100 is installed. As described in additional detail below, embodiments support the configuration of emergency power policies for use by induvial, redundant PSUs 135 (power supply units) of the chassis 100, where such PSU-specific emergency power policies support the continued operation of the chassis by preventing additional power failures and that also support the tailored allocation of the available power during an emergency power failure scenario.

Embodiments of chassis 100 may include a wide variety of hardware configurations in which one or more IHS 105a-n, 115a-n are installed in chassis 100. Such variations in hardware configurations may result from chassis 100 being factory assembled to include components specified by a customer that has contracted for manufacture and delivery of chassis 100. Upon delivery and deployment of a chassis 100, the chassis 100 may be modified by replacing and/or adding various hardware components, in addition to replacement of the removeable IHSs 105a-n, 115a-n that are installed in the chassis. In addition, once the chassis 100 has been deployed, firmware and other software used by individual hardware components of the IHSs 105a-n, 115a-n, or by other hardware components of chassis 100, may be modified in order to update the operations that are supported by these hardware components.

Chassis 100 may include one or more bays that each receive an individual sled (that may be additionally or alternatively referred to as a tray, blade, and/or node) IHSs, such as compute sleds 105a-n and/or storage sleds 115a-n. Chassis 100 may support a variety of different numbers (e.g., 4, 8, 16, 32), sizes (e.g., single-width, double-width) and physical configurations of bays. Embodiments may include additional types of sleds that provide various storage, power, networking and/or processing capabilities. For instance, sleds installable in chassis 100 may be dedicated to providing power supplies units (PSUs) and/or network switch functions. Sleds may be individually installed and removed from the chassis 100, thus allowing the computing and storage capabilities of a chassis to be reconfigured by swapping the sleds with different types of sleds, in some cases at runtime without disrupting the ongoing operations of the other sleds installed in the chassis 100.

Multiple chassis 100 may be housed within a rack. The modular architecture provided by the sleds, chassis and racks allow for certain resources, such as cooling, power and network bandwidth, to be shared by the compute sleds 105a-n and storage sleds 115a-n, thus providing efficiency improvements and supporting greater computational loads. For instance, certain computational workloads, such as computations used in machine learning and other artificial intelligence systems, may utilize computational and/or storage resources that are shared within an IHS, within an individual chassis 100, within a group of chassis 100 installed within a rack and/or within a set of IHSs that may be spread across multiple racks of a data center.

In implementing computing systems that span multiple IHSs 105a-n, 115a-n of chassis 100, such as a vSAN, embodiments may utilize high-speed data links between these resources of the chassis, such as PCIe connections that may form one or more distinct PCIe switch fabrics that are implemented by PCIe controllers 135a-n, 165a-n installed in the IHSs 105a-n, 115a-n of the chassis. These high-speed data links may be used to support applications, such as vSANs, that span multiple processing, networking and storage components of an IHS and/or chassis 100.

Chassis 100 may be installed within a rack structure that provides at least a portion of the cooling utilized by the IHSs 105a-n, 115a-n installed in chassis 100. In supporting airflow cooling, a rack may include one or more banks of cooling fans that may be operated to ventilate heated air from within the chassis 100 that is housed within the rack. The chassis 100 may alternatively or additionally include one or more cooling fans 130 that may be similarly operated to ventilate heated air away from sleds 105a-n, 115a-n installed within the chassis. In this manner, a rack and a chassis 100 installed within the rack may utilize various configurations and combinations of cooling fans to cool the sleds 105a-n, 115a-n and other components housed within chassis 100.

The sled IHSs 105a-n, 115a-n may be individually coupled to chassis 100 via connectors that correspond to the bays provided by the chassis 100 and that physically and electrically couple an individual sled to a backplane 160. Chassis backplane 160 may be a printed circuit board that includes electrical traces and connectors that are configured to route signals and power between the various components of chassis 100 that are connected to the backplane 160 and between different components mounted on the printed circuit board of the backplane 160. In the illustrated embodiment, the connectors for use in coupling sleds 105a-n, 115a-n to backplane 160 include PCIe couplings that support high-speed data links with the sleds 105a-n, 115a-n, 145. In various embodiments, backplane 160 may support various types of connections, such as cables, wires, midplanes, connectors, expansion slots, and multiplexers. In certain embodiments, backplane 160 may be a motherboard that includes various electronic components installed thereon.

In certain embodiments, each individual compute/storage sled 105a-n, 115a-n may be an IHS. Sleds 105a-n, 115a-n may individually or collectively provide computational processing resources that may be used to support a variety of e-commerce, multimedia, business and scientific computing workloads, including machine learning and other artificial intelligence systems. Sleds 105a-n, 115a-n are regularly configured with hardware and software that provide leading-edge computational capabilities. Accordingly, services that are provided using such computing capabilities that are provided as high-availability systems that operate with minimum downtime, such as in edge computing environments.

As illustrated, each compute sled 105a-n and storage sled 115a-n includes a respective remote access controller (RAC) 110a-n, 120a-n, where a RAC may instead be referred to as a baseboard management controller (BMC). Remote access controller 110a-n, 120a-n provides capabilities for remote monitoring and management of a respective compute sled 105a-n or storage sled 115a-n. In support of these monitoring and management functions, remote access controllers 110a-n may utilize both in-band and side-band (i.e., out-of-band) communications with various managed components of a respective compute sled 105a-n or storage sled 115a-n. Remote access controllers 110a-n, 120a-n may collect various types of sensor data, such as collecting temperature sensor readings that are used in support of airflow cooling of the chassis 100 and the sleds 105a-n, 115a-n. In addition, each remote access controller 110a-n, 120a-n may implement various monitoring and administrative functions related to a respective sleds 105a-n, 115a-n, where these functions may be implemented using sideband bus connections with various internal components of the chassis 100 and of the respective sleds 105a-n, 115a-n.

The remote access controllers 110a-n, 120a-n that are present in chassis 100 may support secure connections with a remote management interface 101. In some embodiments, remote management interface 101 provides a remote administrator with various capabilities for remotely administering the operation of an IHS, including initiating updates to the software and hardware operating in the chassis 100. For example, remote management interface 101 may provide capabilities by which an administrator can initiate updates to the firmware utilized by hardware components installed in a chassis 100. In some instances, remote management interface 101 may utilize an inventory of the hardware, software and firmware of chassis 100 that is being remotely managed through the operation of the remote access controllers 110a-n, 120a-n. The remote management interface 101 may also include various monitoring interfaces for evaluating telemetry data collected by the remote access controllers 110a-n, 120a-n. In some embodiments, remote management interface 101 may communicate with remote access controllers 110a-n, 120a-n via a protocol such the Redfish remote management interface.

In the illustrated embodiment, chassis 100 includes one or more compute sleds 105a-n that are coupled to the backplane 160 and installed within one or more bays or slots of chassis 100. Each of the individual compute sleds 105a-n may be an IHS. Each of the individual compute sleds 105a-n may include various different numbers and types of processors that may be adapted to performing specific computing tasks. In the illustrated embodiment, each of the compute sleds 105a-n includes a PCIe controller 135a-n that facilitates high speed access to computing resources of the sled, such as hardware accelerators, DPUs, GPUs, Smart NICs and FPGAs. These computing resources may be programmed and adapted for specific computing workloads, such as to support machine learning or other artificial intelligence systems. In some embodiments, the computing resources of compute sleds 105a-n may be used to implement a vSAN that provides operation of multiple storage resources as a single, logical storage drive. Such vSANs of chassis 100 may support redundant data storage that mirrors data across multiple different storage resources.

As illustrated, chassis 100 includes one or more storage sleds 115a-n that are coupled to the backplane 160 and installed within one or more bays of chassis 100 in a similar manner to compute sleds 105a-n. Each of the individual storage sleds 115a-n may include various different numbers and types of storage devices. A storage sled 115a-n may be an IHS that includes multiple storage drives 175a-n, where the individual storage drives 175a-n may be accessed through a PCIe controller 165a-n of the respective storage sled 115a-n. In some embodiments, these storage drives 175a-n may be pooled as part of a vSAN that provides redundant data storage, such that a failure, replacement or unavailability of any of the pooled storage drives does not render data lost or unavailable.

In addition to the data storage capabilities provided by storage sleds 115a-n, chassis 100 may provide access to other vSAN storage resources that may be installed as components of chassis 100 and/or may be installed elsewhere within a datacenter that houses the chassis 100. In certain scenarios, such storage resources 155 may be accessed via a SAS expander 150 that is coupled to the backplane 160 of the chassis 100. The SAS expander 150 may support connections to a number of JBOD (Just a Bunch Of Disks) storage drives 155 that, in some instances, may be configured and managed to support data redundancy using the various drives 155.

As illustrated, the chassis 100 of FIG. 1 includes a network switch 140, such as a PCIe switch, that provides network access to the sleds 105a-n, 115a-n installed within the chassis. In some instances, network switch 140 may be an integrated component of a backplane 160 or other circuit board of chassis 100. In some instances, network switch 140 may be a replaceable component of chassis 100, such as replaceable sled that is received in a bay of the chassis 100. Network switch 140 may provide components of chassis 100 with access to external networks, either directly or indirectly via additional networking components. In some embodiments, network switch 140 may also support networking within the components of chassis 100, such as via a PCIe switch fabric that provides communications between each of the sleds 105a-n, 115a-n that are coupled to the chassis 100, and that may be used in the operation of a storage network, such as a vSAN, using the resources of chassis 100.

Chassis 100 may also include various I/O controllers that may support various I/O ports, such as USB ports that may be used to support keyboard and mouse inputs and/or video display capabilities. Such I/O controllers may be utilized by a chassis management controller 125 to support various KVM (Keyboard, Video and Mouse) capabilities that provide administrators with the ability to operate the IHSs installed in chassis 100.

In addition to providing support for KVM capabilities for administering chassis 100, chassis management controller 125 may support various additional functions for sharing the infrastructure resources of chassis 100. Chassis management controller 125 may be a include a microcontroller other logic unit that implements various management operations with respect to integrated and replaceable components of chassis 100, including operations for management of sleds 105a-n, 115a-n. In some scenarios, chassis management controller 125 may implement tools for managing power 135, bandwidth available through network switch 140 and/or airflow cooling 130 that are available via the chassis 100.

In embodiments, chassis 100 may also include multiple, redundant power supply units 135 that provide the components of the chassis with various levels of DC power. In certain embodiments, each of the redundant power supply units 135 may be implemented as a replaceable sled, such that the multiple such power supply sleds may be used to provide chassis 100 with redundant, hot-swappable power supply units. As described in additional detail below, the redundant power supply units (PSUs) 135 of chassis 100 may provide redundant sources of power, where each of the power supply units may be connected to different power grids.

In existing systems that utilize redundant power supplies, a failure in any one of these redundant power supplies can result in large deviations in the other redundant power supplies that remain operational. These issues are exacerbated by limitations in existing systems that utilize a single, static protection policy that protects all of the redundant power supplies in the system. In embodiments, emergency rack protection policies provide configurable emergency power limitations the govern the operation of individual power supplies in the system and/or by groups of power supplies. Through the use of such policies, embodiments support the configuration of still-operational power supplies in a manner that allows continued operation of the chassis 100 in emergency power failure scenarios, while also tailoring the emergency power protection that is provided to operate within specific limitations of the power distribution system, such as within power restrictions on specific hardware components of the power distribution system.

For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), a network storage device, or any other suitable device and may vary in size, shape, performance, functionality, and price. An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. As described, an IHS may also include one or more buses operable to transmit communications between the various hardware components. An example of an IHS is described in more detail below.

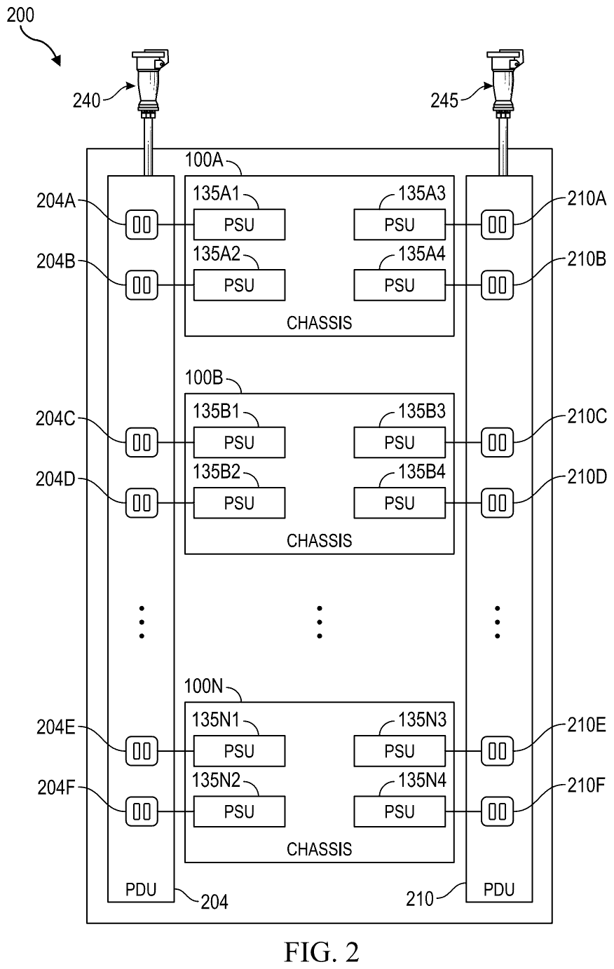

FIG. 2 is a rear-facing illustration of certain components of an rack power distribution system 200 configured, according to some embodiments, to support redundant power supplies that are operated using emergency rack protection policies. As described with regard to FIG. 1, a chassis 100 housing one or more IHSs 105a-n, 115a-n may be installed in a rack. As illustrated in FIG. 2, multiple such chassis 100a-n may be mounted within a rack. In various embodiments, the chassis 100a-n that are installed in the rack and that are powered via the rack power distribution system 200 may be identical with respect to the IHS and other hardware that is installed in each chassis, or some or all of the chassis 100a-n may vary with regard to the IHSs and other hardware installed in each individual chassis. In embodiments, each chassis 100a-n installed in the rack my be powered by the power distribution system 200 of the rack. In particular, each of the chassis 100a-n installed in the rack may utilize redundant sources of power provided by the rack's power distribution system 200.

The illustrated rack power distribution system 200 includes two power distribution units (PDUs) 204, 210 that support power delivery to one or more of the chassis 100 installed in the rack. In the illustrated embodiment, each of the PDUs 204, 210 is coupled to a separate power grid via power connectors 240, 245, where these connectors may be referred to as PDU whips. Based on the coupling of these PDU whips 240, 245, each of the PDUs 204, 210 may receive power from a separate power grid, or may receive power from the same power grid. In embodiments, each of the PDU whips 240, 245 may be connected to a separate power grid such as to separate datacenter power circuits that are separately powered by a local power utility company, an on-site generator, a renewable energy source, etc.

Through these redundant power couplings provided by PDU whips 240, 245, each of the PDUs provide power to the chassis 100a-n that are installed in the rack. In embodiments, the redundant sources of power provided via PDU whips 240, 245 may be used to provide each individual chassis 100a-n with additive power resulting from combining the power delivered from the different power sources, or may be used to provide each individual chassis 100a-n with auxiliary power, where one power source is used as the primary source of power for a chassis and the other source is a backup power source.

In the illustrated embodiment, the rack 200 includes multiple chassis 100a-n, such as described with regard to FIG. 1, where each chassis may include one or more IHSs 105a-n, 115a-n that may be used in implementing high-availability computing systems. As described above, each individual chassis 100 may include multiple power supply units (PSUs) 135. In the rack 200 of FIG. 2, chassis 100a is powered by four PSUs 135a1-4, chassis 100b is powered by four PSUs 135b1-4 and chassis 100n is powered by four PSUs 135n1-4. In other embodiments, a chassis 100a-n may be powered by different numbers of PSUs. In some embodiments, all chassis 100a-n in a rack may be powered using the same number of redundant PSUs, while other embodiments may operate with some or all of the chassis 100a-n utilizing different numbers of PSUs. As such, embodiments may utilize various combinations of PSU configurations, with embodiments providing emergency rack protection procedures for use by these chassis that utilize redundant PSUs that connect to different power grids in scenarios where a failure occurs within one of these grids of the power distribution system. Such failures may be a failure in the source of power for a grid, such as an outage in the local power utility (e.g., transformer failure, downed power lines). Such failures may also result in a temporary outage in a power grid that may result from a variety of components within the power distribution system 200 triggering the outage (e.g., one or more circuit breakers being tripped, fuses being blown, hard resets within the power grid hardware).

Each of the PSUs 135a1-4, 135b1-4, 135n1-4 of the chassis 100a-n that are installed in the rack receive power through couplings with PDUs (power distribution units) 204, 210 of the rack's power distribution system 200. In some embodiments, each PSU may be powered through couplings with outlets provided by these PDUs. In the illustrated embodiment, PSU 135a1 of chassis 100a is powered through a coupling with outlet 204a of PDU 204 and PSU 135a2 is powered through a coupling with outlet 204b. As illustrated, chassis 100 is provided with redundant power through powering of PSU 135a3 through a coupling with outlet 210a of PDU 210 and powering of PSU 135a4 through a coupling with outlet 210b of PDU 210, where PDU 210 draws power from a different power grid than PDU 204

As illustrated in FIG. 2, each of the PDUs 204, 210 is separately powered, with PDU 204 powered by a grid connection provided by PDU whip 240 and PDU 210 powered by a grid connection provided by PDU whip 245. Through these independent power couplings provided by PDU whips 240, 245, each of the PDUs 204, 210 may serve as redundant sources of power for each of the chassis 100a-n that are installed in the rack. By coupling some of an individual chassis' PSUs to each of the separately powered PDUs, the IHSs installed in that particular chassis can be provided with redundant sources of power.

As described, upon a failure in one of these redundant sources of power used by a chassis, existing power systems may be unable to prevent additional faults from occurring throughout a chassis and/or rack, where the faults may result from cascading deviations in voltage and/or current in the chassis' power distribution system. For instance, failure in one of the redundant power grids may result in spikes in voltage and/or current in the still-operational power grid that can trip circuit breakers, blow fuses or otherwise violate thresholds that can result in downtime of IHSs 105a-n, 115a-n, a chassis 100 or an entire rack.

Such faults caused by failures in one of the redundant power grids may result from a single current limit enforced by existing power distribution systems being exceeded. For instance, a failure in one of the redundant power grids may result in a spike in current drawn from the other power grid, where the spike in current exceeds the current limit of the PDU whip or other components of the still-operational power grid, thus resulting in circuit breakers of the PDU or other elements of the still-operational power grid being tripped. Such scenarios may thus result in undesirable damage and/or downtime in components connected to the power gird. Existing systems may provide static protection for a complete rack power distribution system through use of a single current limit that is applicable to each of the PDUs in the system, and thus for all PSUs that are coupled to those PDUs. Once this single current limit is exceeded, all PSUs coupled to a PDU may be affected, with resulting cascading deviations causing failures throughout the rack power distribution system.

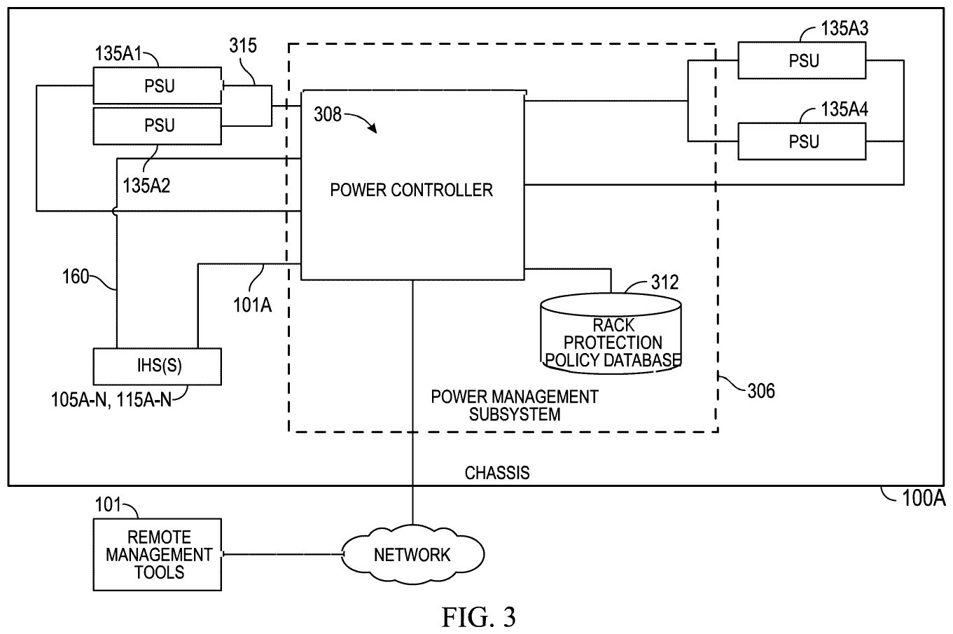

FIG. 3 is an illustration of certain hardware components of a power distribution system of a chassis that is configured, according to some embodiments, to support redundant power supplies that are operated using emergency rack protection policies. In FIG. 3, a chassis 100a, such as described with regard to FIG. 2, includes four PSUs 135a1-4 that provide the chassis with redundant sources of power. For instance, two sources of redundant power may be provided for components of chassis 100a by connecting PSUs 135a1 and 135a2 to a PDU that is coupled to one power grid and connecting PSUs 135a3 and 135a4 to a PDU that is coupled to a different power grid.

As described above, chassis 100a may include multiple IHSs 105a-n, 115a-n, as well as a variety of additional storage, networking, cooling and other hardware resources. Using power drawn from two or more different power grids by PSUs 135a1-4, each of these hardware components of chassis 100a may be redundantly powered. As illustrated, chassis 100a may include a power distribution system 306 that manages the power available for use by IHSs 105a-n, 115a-n and other hardware installed in the chassis through configuration of the PSUs 135a-4 in use by the chassis.

In some embodiments, the power distribution system 306 of a chassis may implement policies for use in managing the power that is drawn by the PSUs 135a1-4 of chassis 100a during emergency scenarios where a failure has occurred in one or more of the sources of redundant power, whether the failure is to an entire grid, to a bank of outlets of a PDU and/or to one or more of the PSUs 135a1-4. In embodiments, separate emergency rack protection policies may be specified for use by each individual PSU 135a1-4 of a chassis.

As described in additional detail below, using such PSU-specific emergency power polices, the power that remains available upon a failure in one of the redundant power sources may be allocated for greater use by a specific chassis installed in the rack, or use by a specific PSU, or use by a specific bank of outlets of a PDU. Embodiments thus also support allocation of limited power available for use during an emergency scenario by specific components and/or subsystems of a rack's power distribution system, thus protecting these components from the possibility of additional power failures.

In some embodiments, these emergency rack protection policies used to protect a chassis and rack may be stored in a device of the chassis 100a, such as in an emergency rack protection policy database 312 that is configured to store policies and other information utilized by the power distribution system 306 of a chassis.

In some embodiments, the power management system 306 may operate through operations of a power controller 308 that runs power management firmware, or other instructions, that may implement the emergency rack protection policies described herein. In some embodiments, the power controller 308 may be implemented by operations of a Baseboard Management Controller (BMC) installed in chassis 100a. In some embodiments, the power controller 308 may be implemented by operations of a remote access controller installed in an IHS 105a-n, 115a-n of chassis 100a. In some embodiments, the power controller 308 may be implemented by operations of a chassis management controller 125 installed in chassis 100a. Through embodiments, a power controller 308, such as a BMC, may interface with other power controllers of other chassis installed in the same rack in configuring the PSU current limits to be used for allocation of emergency power in a manner that prevents further power failures, such as through PSU current limits that adhere to power restrictions of the still-operational power grid(s).

Through operations implemented by the power controller 308, various power management functions may be provided for use in powering components of chassis 100a. In some embodiments, the operations of power controller 308 may include the configuration of current limits used by each of the individual PSUs 135a1-4. In some embodiments, the firmware of power controller 308 may interface with a controller or other logic unit of PSUs 135a1-4 in configuring current limits or other limitations on the power that is drawn by a respective PSU. Through configuration of such current limits of a PSU, the power controller 308 may configure the maximum amount of power that may be drawn by a specific PSU during emergency power scenarios. In some instances, PSUs 135a1-4 may be configured through embodiments to equally share available power during emergency scenario, such that each individual PSU may be configured with the ability draw power and to provide power to IHSs 105a-n, 115a-n in equal amounts.

As described in additional detail below, in some embodiments, the operations of power controller 308 may also be used configure different thresholds that limit the power drawn by each of the PSUs 135a1-4, thus prioritizing the use of power by certain PSUs through the selection of higher current limits and/or providing additional protection to certain PSUs through the selection of lower current limits. The protection that is provided may be further tailored to provide additional protection or additional power to subsystems of the power distribution system, such as to specific banks of PDU outlets or for a specific power grids.

As illustrated, the power controller 308 may be coupled to each of the IHSs 105a-n, 115a-n via both inband 160 and sideband 101a communication couplings, such as described with regard to FIG. 1. Through such connections, the power controller 308 of a chassis 100a may monitor the power drawn by computing components of chassis 100a, and my configure power delivery to these components accordingly. Also as illustrated, power controller 308 may include communication couplings 315 that connect to each of the PSUs 135a1-4 of the power distribution subsystem 306.

Via these connections 315, power controller 308 may implement emergency rack protection policies that configure limits on the maximum power that will be drawn by each of the individual PSUs 135a1-4. Unlike existing systems that use single, static current limits for use throughout a power distribution system, the power controller 308 may implement different power policies for each of the PSUs 135a1-4 installed in the chassis 100a. Through the selection and configuration of such emergency rack protection policies used by individual PSUs in use by a chassis, the power controller 308 may be used in implementing policies that limit the power that can be drawn from a specific power grid and/or from a bank of outlets of a PDU that draws power from a grid. In supporting different emergency power policies for individual PSUs of a chassis 100a, embodiments may thus provide configurable power protection capabilities that may be used to allocate emergency power such that further power failures are avoided and the provided power protection may be tailored to maintain and prioritize specific computing functions while avoiding any additional power failures that could cause downtime in these computing functions.

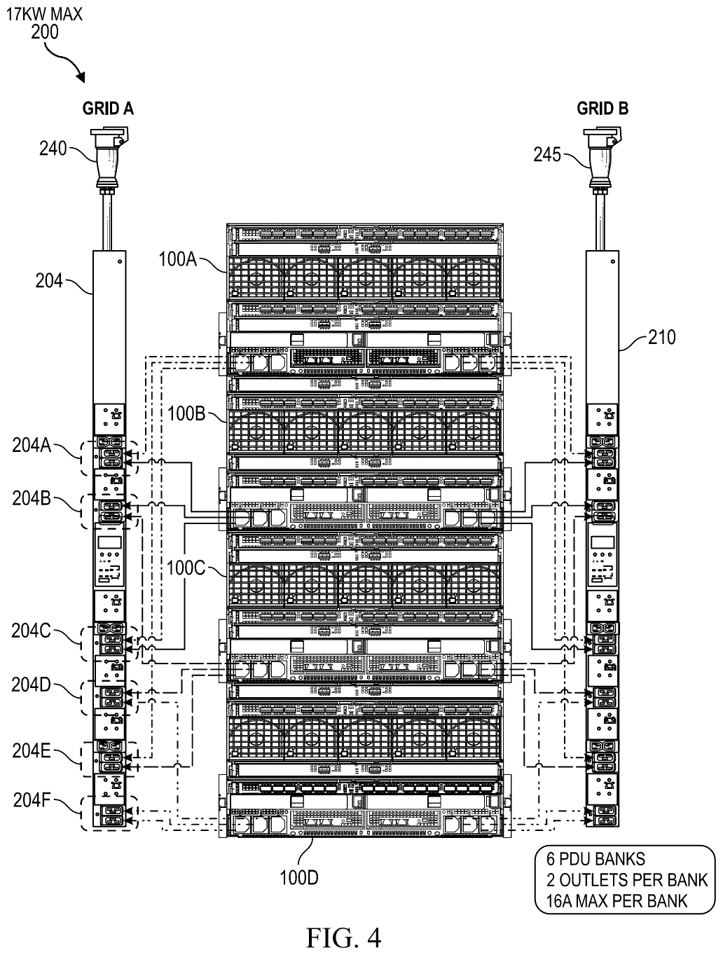

FIG. 4 is a rear-facing illustration of certain components of another rack configured, according to some embodiments, to support two redundant power supplies that are operated using emergency rack protection policies. In the embodiment of FIG. 4, a rack power distribution system 200 provides power for four chassis 100a-d installed in the rack, such as described with regard to FIG. 1. Accordingly, each of the chassis 100a-d may include multiple IHSs and other hardware that operate from redundant sources of power provided by two or more PSUs installed in each of the chassis.

As described with regard to FIG. 2, a rack power distribution system 200 may support redundant power sources through the use of multiple PDUs 204, 210 that are powered from different power grids. PDU 204 may be connected to power grid A via a coupling provided by PDU whip 240 and PDU 210 may be connected to power grid B via a coupling provided by PDU whip 245. In providing redundant power for each of the chassis 100a-d installed in the rack, each of the chassis includes six separate PSUs.

By coupling some of the PSUs to grid A and other PSUs to grid B, each of the chassis 100a-d is provided with redundant sources of power. In some instances, the redundant power from grid A and grid B may be additive power available to the hardware installed in a chassis, while in other instances the redundant power from grid A and grid B may be utilized as a primary power source and a secondary power source that is used when the primary power source is unavailable, or to occasionally provide a boost of additional power.

As illustrated, PDU 204 includes six banks 204a-f of outlets, where each of the banks of outlets may be protected a circuit breaker, fuse or other circuit protection device. Also as illustrated, each chassis 100a-d may be coupled to multiple banks 204a-f of outlets of each of the PDU. For instance, chassis 100a may include power connections from the individual PSUs installed in that chassis, where the connections are distributed between outlets from PDU 204 and outlets from PDU 210. More particularly, the six PSUs of chassis 100a may be coupled to PDU outlets 204a, 204c and 204e drawing power from grid A and coupled to PDU outlets 204b, 204d and 204f drawing power from grid B, where each of these outlet couplings may result in couplings to different banks of the PDU 204 that are each separately protected by circuit breakers.

In some configurations, each of the chassis 100a-d may be configured to draw up to 5,000 W of power, such that the four chassis installed in the rack may together consume up to 20,000 W of power. However, a failure in one of the redundant grids (i.e., failure in grid A or grid B) may require throttling of the power drawn from the grid that remains operational. For instance, power limitations on PDU whips 240, 245 may prevent operation of the rack at full power from a single power grid. Some PDU whips 240, 245 may be restricted to operating at no more than 17,000 W of power. In such scenarios, the power drawn by the rack from this single grid during a power failure in a redundant grid must be throttled to 17,000 W or less of power, such that each of the four chassis may be limited to use of 4,250 W of power (17,000 W/4 chassis).

In existing systems, a single limit may be placed on the power that may delivered by a grid and that may be drawn at each bank of outlets of a PDU, and thus that may be drawn by each PSU. For instance, in a scenario where a supply grid can provide 208V of power at 60 W, a current limit of 20.5 A (4,250 W/208V) may be set for the grid in existing systems that configure emergency throttling, where this current limit may be further adjusted to approximately 16 A (around 80% of 20.5 A) to provide a margin of error in protecting from spikes in the remaining operational grid that is in use by the rack. Such a limitation may provide overall protection for the PDU whip of the remaining operational grid, but may significantly limit the PSUs that draw power from the still operational grid.

In a scenario where a PDU drawing power from the operational grid is divided into banks of outlets that are each separately protected by circuit breakers, this single current limit that is available in existing systems is the current limit used by each of these circuit breakers.

As described, in response to a grid failure, each chassis may receive up to 4,250 W of throttled power in existing systems that set a single grid limit that is selected to protect the PDU whip of the still-operational grid. Based on this throttled power delivery, each bank of PDU outlets may thus draw up to approximately 20.5 A of current from the still-operational grid (4,250 W/208V). In a scenario where each PDU bank includes two outlets, two separate PSUs may be coupled to these outlets, such that each PSU may draw approximately 10.25 A of current from the PDU. Two PSUs drawing the full current from the PDU results in 20.5 A of current being drawn, which is above the 16V current limit set that has been set for the still-operational grid. Accordingly, use of a single current limit for an entire grid may result in circuit breakers being tripped in the PDU, thus resulting in possible downtime. The tripping of circuit breakers may additionally result in additional spikes in current drawn by other PSUs, which may result in additional cascading failures during the unstable power interval.

In embodiments, separate power limits may be used for each of the redundant grids/PDUs used by a rack power distribution system, and for each of the PSUs that are coupled to the power distribution systems that are redundantly drawing power from each of the grids. As indicated in FIG. 4, each chassis 100a-d may include six PSUs, with three PSUs connected to one of the redundant power grids and the other three PSUs connected to the other of the redundant power grids. As illustrated, PSUs of chassis 100a are coupled to outlets in three separate PDU bank 204a, 204c and 204e, as well as to outlets in three separate PDU banks from the other power grid. In this manner, each of the PSUs of chassis 100a draws power from a different PDU bank, and is thus protected by a different circuit breaker. Whereas existing system operate using a single current limit for all the components drawing power from a grid, in embodiments each of the PSUs of chassis 100a may be separately protected by individual current or power limits.

As described with regard to FIG. 3, each chassis 100a-d may operate using a power controller that manages the power drawn from the PSUs that are installed in that particular chassis. In embodiments, software operated by the power controller of each chassis 100a-n may be utilized in implementing current limits that are used by each of the individual PSUs that are in use by the chassis. For instance, a current limit of 8 A may be set for each of the PSUs of each chassis 100a-d. During a failure in one grid, this 8 A current limit allows two PSUs to each draw power from two outlets of a PDU bank and draw up to 16 A of current, within the grid limits that can safely protect all of the hardware in a rack, while also providing sufficient power for operations to continue throughout the rack without downtime. Such operations may continue at throttled power levels, but further power failures are prevented, with both PSUs drawing power from that bank of the PDU being provided enough power to continue operation of a chassis.

Through configurations of PSU outlet couplings such as illustrated in FIG. 4 and utilizing improvements provided by embodiments for enforcing separate current limits for each individual PSU in use by a chassis, each chassis that is redundantly powered via two redundant power grids may be separately protected from failures in either of these grids. Through embodiments, a chassis may be configured to preserve operations without downtime using a remaining power grid in response to a failure in a redundant power grid, while also providing the ability to utilize policies for use in tailoring the allocation of available power during such emergency failover scenarios.

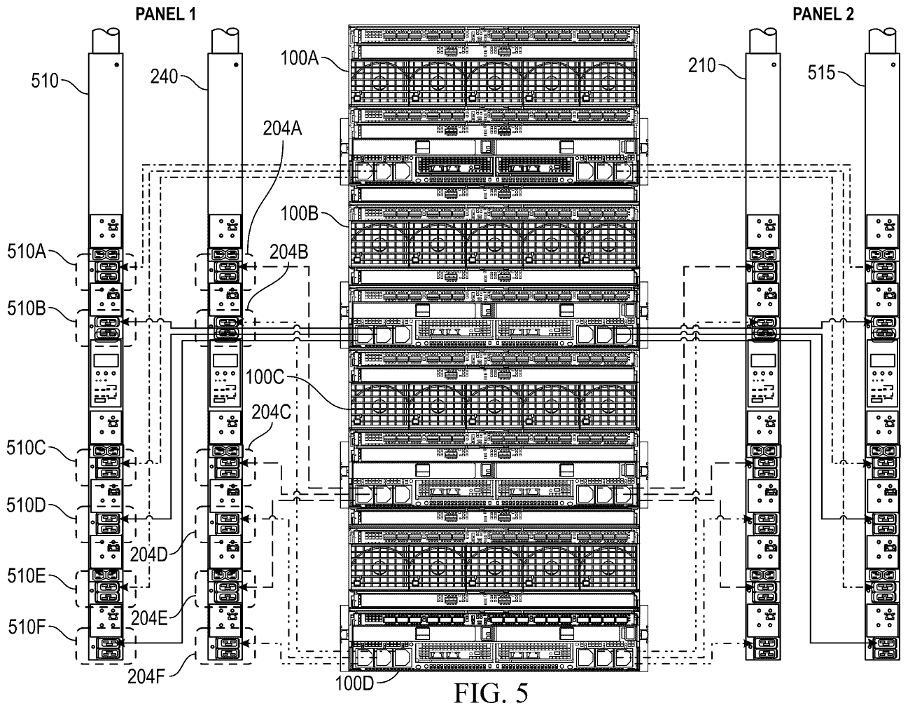

FIG. 5 is a rear-facing illustration of certain components of another rack configured, according to some embodiments, to support four redundant power supplies that are operated using emergency rack protection policies. In the embodiment of FIG. 4, two redundant power grids may be utilized by a chassis 100a-d, thus providing each chassis with a source of a failover power in scenarios where one of the power grids fails. In the embodiment of FIG. 4, two redundant grids (Grid A and Grid B) may be utilized by a chassis, with PSUs from each chassis 100a-d connected to both of these grids. Through embodiments, a chassis may operate PSUs according to individual current limits, thus enabling the use of different emergency power policies for PSUs that draw power from different grids.

In the embodiment of FIG. 5, four separate power grids (Grids A, B, C and D) may be available for use by a rack power distribution system. As illustrated in FIG. 5, multiple grids may be grouped into power panels, where Grids A and C are grouped as Panel_2 and Grids B and D are grouped as Panel_1. In such configurations, embodiments support the ability to utilize different emergency power policies for individual grids and for groups of grids, such as separate polices for components of each of the panels illustrated in FIG. 5. Through embodiments, PSUs may operate according to multiple different emergency power policies. For instance, a PSU may operate using a policy specifying a current limit for drawing power from a specific grid and also using a policy specifying a current limit for drawing power from a collection of grids, such as from one of the illustrated panels.

In this manner, embodiments provide capabilities for a chassis to operate using different policies that are tailored to the different grids or collection of grids that remain available for use by the chassis during emergency power grid failures. For instance, in the configuration illustrated in FIG. 5, the PSUs of chassis 100a may be configured for use of multiple emergency rack protection policies, with a different policy used for each grid and for each group of grids to which an individual PSU is coupled. For instance, PSUs 1, 2 and 3 of chassis 100a may be governed by a grid policy for drawing power from the PDU 515 of one grid and may be governed by a separate grid policy for drawing power from the group of grids of Panel 2, that provides power via PDU 210 and PDU 515.

Through the use of multiple grid policies provided by embodiments, emergency power failure scenarios may include mitigations that are tailored to powering the chassis or other components of the rack that are highest in priority with respect to avoiding any downtime. Moreover, embodiments allow the tailoring of available power based on the capabilities of different grids and collections of grids that remain operational. For instance, in the embodiment of FIG. 5, the grids 210, 515 that are grouped into Panel 2 may be utilized by the PSUs of chassis 100a according to one grid policy that allows for a greater current draw across the two grids 210, 515 of the panel, in addition to also enforcing other grid policies that restricts the individual PSUs of chassis 100a to a more limited current draw from the individual grid 515. In this manner, current limits that protect PDU whips of individual grids 210, 515 may be utilized when drawing power from a single grid, but higher current limits may be utilized when drawing power from multiple grids, and thus from multiple PDU whips, such that power limits on PDU whips are respected during failures in redundant power delivery components of a power distribution system.

The use of multiple emergency rack protection policies that may be used by the PSUs of a chassis may also be used to tailor the protection provided for different grids. For instance, in the configuration illustrated in FIG. 5, grid 210 may provide power from a local power utility and grid 515 may provide power that is generated using renewable energy resources. In some instances, the renewable energy of grid 515 may have lower and/or different power delivery capabilities than the grid 210 drawing power from the utility company. As such, grid policies used to govern power drawn from the renewable energy grid 515 may specify lower current limits than the limits that are used in the grid policies used to govern power drawn from the utility company grid 210.

In addition to supporting operations during emergency scenarios within the power constraints of specific grids and/or constraints of the PDU whips used to couple PDUs of the power distribution system to the respective grids, embodiments support emergency power policies that are tailored to protecting specific banks of a PDU. As illustrated in FIG. 5, PSUs 4,5,6 of chassis 100a are coupled to PDU 510, with one PSU coupled to outlet 510a in one bank of PDU 510, another PSU coupled to outlet 510c of another bank of PDU 510 and another PSU coupled to outlet 510e of another bank of PDU 510. In this same manner, PSUs of chassis 100b are coupled to outlets 510b, 510d, and 510f of PDU 510, such that each of these PSUs are coupled to different PDU banks In such a configuration, the PSUs connected to outlets 510a and 510b may share PDU bank, the PSUs connected to outlets 510c and 510d share another PDU bank and PSUs connected to outlets 510e and 510f share another PDU bank.

In such configurations, the emergency rack protection policies used by individual PSUs according to embodiments may be tailored to constraints or other aspects of a specific PDU bank. For instance, the PSUs of chassis 100a that are coupled to PDU 510 may be configured to operate using lower current limits than the PSUs of chassis 100b that are coupled to PDU 510. Through use of such PSU-specific emergency rack protection policies, embodiments allow more available power to be used by chassis 100b in emergency power scenarios compared to chassis 100a, thus allowing chassis 100a to remain operational, but to enable greater use of emergency power by chassis 100b and thus to retain computing power for certain critical operations of chassis 100b.

In other scenarios, embodiments may utilize PSU-specific emergency rack protection policies to prioritize the power and protection provided to specific banks of outlets of a PDU. For instance, in the configuration of FIG. 5, the PSUs of chassis 100a and 100b that are coupled to outlets 510a and 510b, and that are thus in the same PDU bank, may be configured to use policies with different current limits than used by the emergency policies used by other PSUs that are coupled to the other banks of outlets 510c-f of this PDU 510. Configured in this manner, embodiments may allow emergency power to be differently allocated among the PDU banks. Lower current limits may be set for PSUs connecting to certain PDU banks that are of lesser priority or to provide maximum protection from further outages. In this same manner, higher current limits may be set for PSUs connecting to other PDU banks, thus providing greater emergency power to these higher priority PDU banks. Through the configuration of PSU-specific emergency power policies, embodiments support the tailored allocation of available emergency power towards or away from specific PDU banks.

In some embodiments, the thresholds used by emergency rack protection policies may be adjusted based on characteristics of the power failure that has necessitated the initiation of the emergency rack protection policies. For instance, some embodiments may characterize the health of a PDU by identifying the number of PSUs that are coupled to the PDU that have failed in relation to the number of PSUs coupled to that PDU that remain operational. In some embodiments, the health of an individual chassis may be similarly determined based the number of PSUs of that chassis that have failed versus those that remain operational. In this same manner, the health of a grid or of a panel formed from a group of grid inputs may be calculated based on the numbers of failed and operational PSUs that are coupled to a grid, or to the panel. In this same manner, the health of specific banks of outlets in a PDU may be calculated based o the number of failed and operational PSUs that are connected to outlets of a respective PDU bank.

Based on such health characteristics of the power distribution system, embodiments may dynamically configure the thresholds of rack protection policies used by specific PSUs in the power distribution system. For instance, current limits may be adjusted upwards when for use in healthier subsystems of the power distribution system, such as adjusting current limits upwards for PSUs that are coupled to the most healthy grid and/or the most healthy PDU that remains operational. Conversely, embodiments may be used to adjusted current limits downwards for rack protection policies of PSUs that are coupled to the least healthy grid and/or least healthy PDU that remains operational. In some embodiments, the thresholds used by rack protection policies of individual PSUs may be dynamically adjusted to correspond to the health of the environment in which the individual PSU is operating.

In this manner, greater portions of the available power may be directed for use by the healthiest subsystems of a rack. In some embodiments, the dynamic adjustment of current limits used by rack protection policies may result in available power being diverted away from subsystems that are below a minimum health level. For instance, embodiments may specify that a PDU bank and/or grids must have at least a certain number of healthy, operational PSUs in order for that PDU bank and/or grid to be allocated any of the available emergency power. For instance, embodiments may adjust the rack protection policy to utilize a zero current limit for all PSUs (i.e., cutting off the ability for the PSU to draw power) that are connected to a grid that does not have a minimum number of healthy PSUs operating. In this manner, available power may be diverted away from the subsystems of the power distribution system that are currently not healthy enough to operate at full performance, and instead divert available power towards the healthy subsystems of the power distribution system that can be operated at least up to the throttled levels that can currently be supported based on the available power.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A power distribution system for powering a chassis installed in a rack, the system comprising:
two or more power supply units (PSUs) installed in the chassis,
wherein a first of the PSUs is coupled to a first power grid supplying power to the rack, and
wherein a second of the PSUs is coupled to a second power grid supplying power to the rack, and
wherein power drawn from the first power grid by the first PSU is limited according to a first current limit specified in a first emergency rack protection policy of the rack upon a failure in the second power grid, and
wherein power drawn from the second power grid by the second PSU is limited according to a second current limit specified in a second emergency rack protection policy of the rack upon a failure in the first power grid.

2. The power distribution system of claim 1, wherein the first current limit specified in the first emergency rack protection policy is initiated in response to the failure in the second power grid, and wherein the second current limit specified in the second emergency rack protection policy is initiated in response to the failure in the first power grid.

3. The power distribution system of claim 1, further comprising a first power distribution unit (PDU) and a second PDU, wherein the first PSU draws power according to the first emergency rack protection policy from the first power grid via the first PDU, and wherein the second PSU draws power according to the second emergency rack protection policy from the second power grid via the second PDU.

4. The power distribution system of claim 3, further comprising a first whip coupling the first PDU to the first power grid and further comprising a second whip coupling the second PDU to the second power grid.

5. The power distribution system of claim 4, further comprising a third PSU that is installed in the chassis and that is coupled to the first power grid, wherein power drawn from the first power grid by the third PSU is limited according to a third current limit specified in a third emergency rack protection policy of the rack upon a failure in the second power grid.

6. The power distribution system of claim 5, wherein the first current limit specified in the first emergency rack protection policy and the third current limit specified in the third emergency rack protection policy are selected to comply with power restrictions on the first whip coupling the first PDU to the first power grid.

7. The power distribution system of claim 5, wherein the first PDU comprises a first bank of outlets and wherein the first PSU and the third PSU are coupled to the first power grid via the first bank of outlets of the first PDU.

8. The power distribution system of claim 7, wherein the first current limit specified in the first emergency rack protection policy and the third current limit specified in the third emergency rack protection policy are selected to comply with power restrictions on the first bank of outlets of the first PDU.

9. The power distribution system of claim 2, wherein a health of the first power grid is calculated in response to the failure in the second power grid, wherein the power drawn from the first power grid by the first PSU according to the first emergency rack protection policy is adjusted based on the health calculated for the first power grid.

10. A chassis utilizing a power management system, the chassis comprising:
a plurality of IHSs (Information Handling Systems); and
two or more power supply units (PSUs) providing power to the plurality of IHSs,
wherein a first of the PSUs is coupled to a first power grid supplying power to the rack, and
wherein a second of the PSUs is coupled to a second power grid supplying power to the rack, and
wherein power drawn from the first power grid by the first PSU is limited according to a first current limit specified in a first emergency rack protection policy of the rack upon a failure in the second power grid, and
wherein power drawn from the second power grid by the second PSU is limited according to a second current limit specified in a second emergency rack protection policy of the rack upon a failure in the first power grid.

11. The chassis of claim 10, wherein the first current limit specified in the first emergency rack protection policy is initiated in response to the failure in the second power grid, and wherein the second current limit specified in the second emergency rack protection policy is initiated in response to the failure in the first power grid.

12. The chassis of claim 10, further comprising a third PSU that is installed in the chassis and that is coupled to the first power grid, wherein power drawn from the first power grid by the third PSU is limited according to a third current limit specified in a third emergency rack protection policy of the rack upon a failure in the second power grid.

13. The chassis of claim 12, wherein the first current limit specified in the first emergency rack protection policy and the third current limit specified in the third emergency rack protection policy are selected to comply with power restrictions on a first whip coupling the first PSU and the third PSU to the first power grid.

14. The chassis of claim 10, further comprising a power controller configured to enforce the first current limit used by the first PSU in limiting power drawn from the first power grid according to the first emergency rack protection policy.

15. The chassis of claim 14, wherein the power controller is further configured to enforce the first current limit used by the second PSU in limiting power drawn from the second power grid according to the second emergency rack protection policy.

16. A computer-readable storage device having instructions stored thereon for management of power drawn by a chassis comprising one or more IHSs (Information Handling Systems), wherein execution of the instructions by one or more processors of the chassis causes the one or more processors to:
configure a first PSU of the chassis to draw power from a first power grid supplying power to the rack, wherein power drawn from the first power grid by the first PSU is limited according to a first current limit specified in a first emergency rack protection policy of the rack upon a failure in a second power grid supplying power to the rack; and
configure a second PSU of the chassis to draw power from the second power grid supplying power to the rack, wherein power drawn from the second power grid by the second PSU is limited according to a second current limit specified in a second emergency rack protection policy of the rack upon a failure in the first power grid.

17. The computer-readable storage device of claim 16, wherein the first current limit specified in the first emergency rack protection policy is initiated in response to the failure in the second power grid, and wherein the second current limit specified in the second emergency rack protection policy is initiated in response to the failure in the first power grid.

18. The computer-readable storage device of claim 16, wherein the execution of the instructions further cause the one or more processors of the chassis to configure a third PSU of the chassis that is coupled to the first power grid, wherein power drawn from the first power grid by the third PSU is limited according to a third current limit specified in a third emergency rack protection policy of the rack upon a failure in the second power grid.

19. The computer-readable storage device of claim 18, wherein the first current limit specified in the first emergency rack protection policy and the third current limit specified in the third emergency rack protection policy are selected to comply with power restrictions on a first whip coupling the first PSU and the third PSU to the first power grid.

20. The computer-readable storage device of claim 19, wherein the first current limit specified in the first emergency rack protection policy and the third current limit specified in the third emergency rack protection policy are selected to comply with power restrictions on the a bank of outlets coupling the first PSU and the third PSU to the first whip.
